(19) United States
(12) Patent Application Publication
(10) Pub. No.: US 2017/0069791 A1
(43) Pub. Date: Mar. 9, 2017

(54) LIGHT-EMITTING DEVICE AND METHOD OF MANUFACTURING THEREOF

(71) Applicant: EPISTAR CORPORATION, Hsinchu (TW)

(72) Inventor: Yu-Chen YANG, Hsinchu (TW)

(21) Appl. No.: 14/847,169

(22) Filed: Sep. 8, 2015

(51) Int. Cl. H01L 33/22; H01L 33/00; H01L 33/12

(52) U.S. Cl. CPC H01L 33/22; H01L 33/12; H01L 33/0095; H01L 33/007

(57) ABSTRACT

A light-emitting device comprises a transparent substrate and a light-emitting stack formed on a surface of the transparent substrate, wherein the transparent substrate has a substrate thickness satisfying a light-extraction efficiency of the light-emitting device decreased by no more than 0.1% if the substrate thickness is decreased by 30 μm.

### TECHNICAL FIELD

This present application relates to a light-emitting device, and more particularly to a light-emitting device comprising a transparent substrate. This application further comprises the method of manufacturing the light-emitting device.

### DESCRIPTION OF BACKGROUND ART

Light-emitting diode (LED) is a solid state semiconductor device and generally comprises a p-type semiconductor layer, an n-type semiconductor layer, and an active layer formed between the p-type semiconductor layer and the n-type semiconductor layer for emitting light under the principle of transforming electrical energy to optical energy by injecting electrons and holes through the n-type semiconductor layer and the p-type semiconductor layer respectively to the active layer to perform radiative combination and emit light.

### SUMMARY OF THE DISCLOSURE

The present disclosure provides a light-emitting device comprises a transparent substrate; and a light-emitting stack formed on a surface of the transparent substrate, wherein the transparent substrate has a substrate thickness satisfying a light-extraction efficiency of the light-emitting device decreased by no more than 0.1% if the substrate thickness is decreased by 30 μm.

The present disclosure further provides a light-emitting device comprising a transparent substrate and a light-emitting stack formed on a surface of the transparent substrate, wherein the transparent substrate has a substrate surface area A (mil²) and a substrate thickness T_{sub}(μm) satisfy the following relationship:

T_{sub}≧0.1048×A+115.82.

The present disclosure further provides a method of manufacturing a light-emitting device, comprising steps of determining a substrate surface area and a saturated thickness corresponding to the substrate surface area, providing a transparent substrate having a starting thickness greater than the saturated thickness, forming an epitaxial stack on the transparent substrate, dividing the epitaxial stack into a plurality of light-emitting stacks on the transparent substrate, determining a substrate thickness not less than the saturated thickness, treating the transparent substrate such that the transparent substrate has the substrate thickness, and dicing the transparent substrate to form a plurality of light-emitting dies each with the substrate surface are.

### BRIEF DESCRIPTION OF THE DRAWINGS

FIG. 1 shows a light-emitting device in accordance with one embodiment of the present disclosure.

FIG. 2 shows the relationship between the light-extraction efficiency and the substrate thickness of the light-emitting device in accordance with an embodiment of the present disclosure.

FIG. 3 shows an enlarged view of a portion of the relation curve of the light-extraction efficiency and the substrate thickness in FIG. 2.

FIG. 4 shows the relationship between the light-extraction efficiency and the substrate thickness of the light-emitting device under various substrate surface areas.

FIG. 5 shows the relationship between the saturated thickness and the substrate surface area of the light-emitting device in accordance with an embodiment of the present disclosure.

FIG. 6 shows a lighting apparatus comprising the light emitting device in accordance with one embodiment of the present disclosure.

### DETAILED DESCRIPTION OF THE PRESENT DISCLOSURE

The embodiment of the application is illustrated in detail, and is plotted in the drawings. The same or the similar parts are illustrated in the drawings and the specification with the same reference numeral.

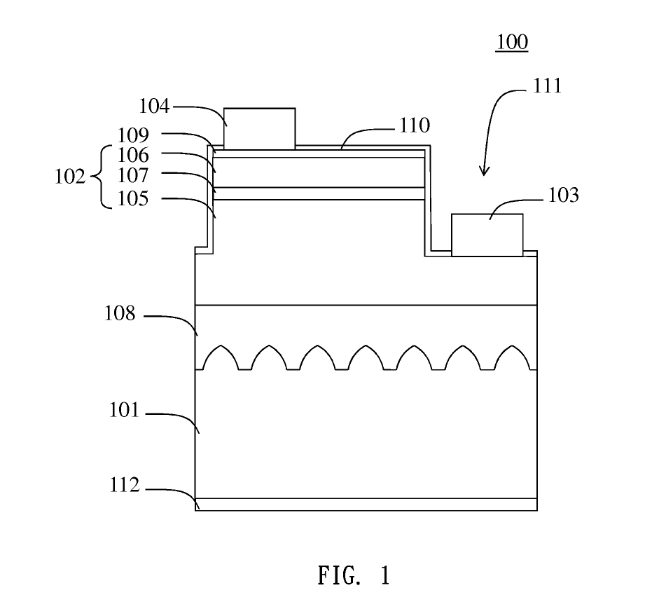

FIG. 1 shows a light-emitting device (LED) in accordance with one embodiment of the present disclosure. The LED 100 comprises a transparent substrate 101, a light-emitting stack 102, a first electrode 103, and a second electrode 104. The light-emitting stack 102 is formed on the transparent substrate 101, and the first electrode 103 and the second electrode 104 are formed on the surface of the light-emitting stack 102.

The purpose of the transparent substrate 101 serves as a support to prevent the light-emitting stack 102 of the LED 100 from breaking during the manufacturing process or the usage of LED 100. The transparent substrate 101 is not limited to single-crystal substrate, it can be poly-crystal or amorphous substrate as well. For example, the material of the transparent substrate 101 is selected from sapphire, glass, Si, GaN, GaP, GaAs, GaAsP, ZnSe, ZnS, or SiC and so on. In the preferred embodiment, the material of the transparent substrate 101 is single-crystal sapphire for growing the light-emitting stack 102 by epitaxy growth method. Furthermore, in order to reduce the total internal reflection (TIR) between the transparent substrate 101 and the light-emitting stack 102 and improve the light-extraction efficiency, the transparent substrate 101 has a textured surface where the light-emitting stack 102 is formed. The transparent substrate 101 is transparent to a light emitted from the light-emitting stack 102, and more precisely, the transmittance of the transparent substrate 101 to the light is higher than 90%. The transparent substrate 101 has a substrate thickness. The dimension of the substrate thickness not only influences the dicing efficiency and yield when producing the LED 100, but also correlative with the light-extraction efficiency. In order to enhance the light-extraction efficiency of the LED 100, there is a limitation on the substrate thickness, and the detail limitation of the substrate thickness will be mentioned later.

The light-emitting stack 102 comprises a first semiconductor layer 105 with a first conductivity-type on the transparent substrate 101, a second semiconductor layer 106 with a second conductivity-type on the first semiconductor layer 105, and an active layer 107 between the first semiconductor layer 105 and the second semiconductor layer 106, as shown in FIG. 1. The light-emitting stack 102 has a low-lying region 111 where exposes a part of the first semiconductor layer 105. The light-emitting stack 102 further comprises a buffer layer 108 overlaying the textured surface of the transparent substrate 101 and locates between the transparent substrate 101 and the first semiconductor layer 105. The second semiconductor layer 106 overlays the active layer 107. The active layer 107 comprises a structure selected from a group consisting of homostructure, single heterostructure (SH), double heterostructure (DH), and multiple quantum wells (MQW). The first conductivity-type is different from the second conductivity-type. For example, the material of the first semiconductor layer 105 and the second semiconductor layer 106 comprise n-type Gallium Nitride (GaN) and p-type Gallium Nitride respectively. The light-emitting stack 102 is formed by a known epitaxy method, such as metallic-organic chemical vapor deposition (MOCVD) method, molecular beam epitaxy (MBE) method, or hydride vapor phase epitaxy (HVPE) method.

In a preferable embodiment, the buffer layer 108 is directly grown on the transparent substrate 101 through epitaxy process when acting as a crystal buffer layer, and therefore, the material of the buffer layer 108 comprises Gallium Nitride (GaN), Aluminum Nitride (AlN), or Aluminum Gallium Nitride (AlGaN). The buffer layer 108 is single-crystal or poly-crystal formed by epitaxial process. Alternatively, the buffer layer 108 could be formed through dielectric bonding process, and therefore, the material of the buffer layer 108 comprises transparent polymer or transparent oxide when acting as a bonding layer for bonding the light-emitting stack 102 to the transparent substrate 101. In a preferable embodiment, the thicknesses of the buffer layer 108 is between 1 μm and 3 μm, the first semiconductor layer 105 is between 2 μm and 6 μm, the active layer 107 is between 0.15 μm and 0.45 μm, and the second semiconductor layer 106 is between 0.1 μm and 0.3 μm.

The first electrode 103 and the second electrode 104 provides a bonding pad for flipped-bonding or wire-bonding to an external power source and introduces current into the light-emitting stack 102 to light up the LED 100. The first electrode 103 is formed on and electrically connects to the first semiconductor layer 105, and the first electrode 103 locates on the low-lying region 111. The second electrode 104 is formed on a transparent conductive oxide layer 109 and electrically connects to the second semiconductor layer 106. The transparent conductive oxide layer 109 is between the second electrode 104 and the second semiconductor layer 106 and forms an ohmic contact with the second semiconductor layer 106 for evenly dispersing the electric current into the light-emitting stack 102. In the embodiment, the material of the transparent conductive oxide layer 109 comprises transparent conductive oxide, such as Indium Tin oxide (ITO). In addition, the LED 100 comprises a passivation layer 110 covered on the top and the sidewall of the light-emitting stack 102 to protect the LED 100 from being damaged by mechanically handling or the corrosion by the environment. In a preferable embodiment, the thicknesses of the transparent conductive oxide layer 109 is between 300 Å and 800 Å and the passivation layer 110 is between 500 Å and 1000 Å. For conducting electric current into the light-emitting stack 102 from the external power source, the surfaces of the first electrode 103 and the second electrode 104 are free of the coverage of the passivation layer 110. In order to reflect the generated light emitting to the transparent substrate 101 and enhance the light extraction efficiency, the LED 100 further comprises a backside reflector 112 located under the transparent substrate 101. The backside reflector 112 is capable of reflecting more than 95% of light incident thereto back to the light-emitting stack 102. In the embodiment, the material of the backside reflector 112 comprises a metal mirror and a DBR (Distributed Bragg Reflector) interposed between the transparent substrate 101 and the metal mirror, The DBR comprises alternately stacked low refractive-index layers and high refractive-index layers, where the low refractive-index layers comprise silicon oxide, and the high refractive-index layers comprises aluminum oxide. The metal mirror comprises Au, Al, or Ag.

The substrate thickness satisfies a light-extraction efficiency of the LED 100 decreased by no more than 0.1% (which means equal to 0.1% or less than 0.1%) if the substrate thickness is decreased by 30 μm. For eliminating the measurement deviation of the light-extraction efficiency, the light-extraction efficiency is averaged through a number of repetitive measurements and calculations, e.g. 20 times or more.

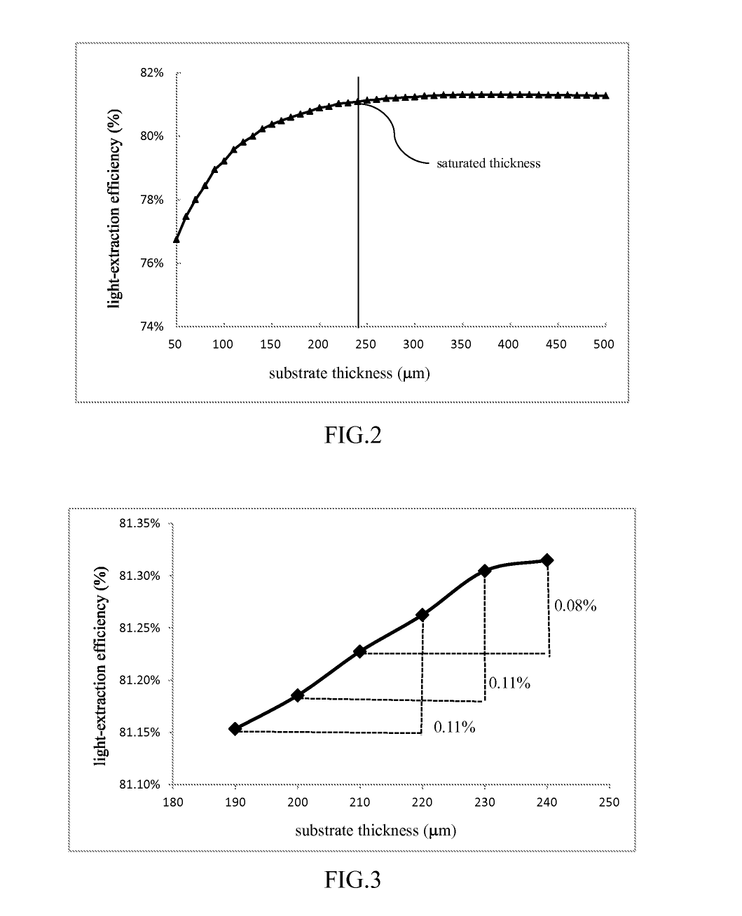

Besides, the transparent substrate 101 has a substrate surface area. FIG. 2 shows the relationship of the light-extraction efficiency of LED 100 versus the substrate thickness at the substrate surface area of 1035 mile². As shown in FIG. 2, the light-extraction efficiency increases notably as the substrate thickness increases from about 50 μm to about 240 μm, and then the increase of the light-extraction efficiency eases after about 240 μm and saturates to be substantially unchanged after a substrate thickness of about 240 μm. The value of 240 μm regards as a saturated thickness of the LED 100 having the substrate surface area of 1035 mile². The saturated thickness is a minimum value of the substrate thickness, which satisfying the light-extraction efficiency of the LED 100 decreased by no more than 0.1% if the substrate thickness is decreased by 30 μm. When the substrate thickness is higher than the saturated thickness, the LED 100 achieves a saturated light-extraction efficiency. Therefore, the external quantum efficiency of the LED 100 can be enhanced by having the substrate thickness larger than the saturated thickness.

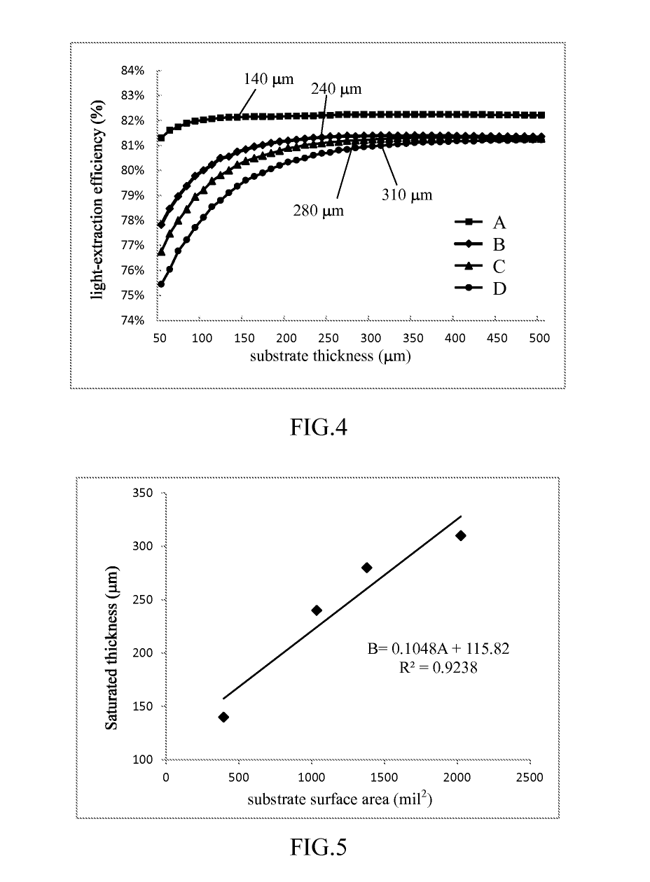

FIG. 3 shows enlarged view of a portion of the relationship curve of the light-extraction efficiency and the substrate thickness in FIG. 2. The light-extraction efficiency decreases by 0.08% when the substrate thickness changes from 240 μm to 210 μm. However, the light-extraction efficiency decreases 0.11% (more than 0.1%) while the substrate thickness changes from 230 μm to 200 μm, and the light-extraction efficiency decreases 0.11% while the substrate thickness changes from 220 μm to 190 μm. Therefore, 240 μm is regarded as the saturated thickness at the substrate surface area of 1035 mil². FIG. 4 shows the relationship between the light-extraction efficiency and the substrate thickness of the LED 100 under various substrate surface areas. The different curves in FIG. 4 indicate the LEDs 100 with different substrate surface areas, which are curve A representing the substrate surface area of 396 mil², curve B representing the substrate surface area of 1035 mil², curve C representing the substrate surface area of 1380 mil² and curve D representing the substrate surface area of 2025 mil² respectively. The saturated thickness of the curve A is about 140 μm, which is the minimal value of the substrate thickness with the substrate surface area of 396 mil² satisfying the light-extraction efficiency being decreased no more than 0.1% when the substrate thickness is decreased by 30 μm. Likewise, the saturated thickness is about 240 μm for the substrate surface area of 1035 mil², the saturated thickness is about 280 μm for the substrate surface area of 1380 mil², and the saturated thickness is about 310 μm) for the substrate surface area of 2025 mil² respectively. Each of the various substrate surface areas corresponds to a distinct saturated thickness, and the saturated thickness substantially increases with the substrate surface area increases.

FIG. 5 shows the relationship between the saturated thickness and the substrate surface area calculated from FIG. 4. The saturated thickness is positively correlated with the substrate surface area. Specifically, the saturated thickness is substantially linearly positively correlated with the substrate surface area by following equation (1) listed below. In the equation (1), A and B represent the substrate surface area (mil²) and the saturated thickness (μm) respectively.

B=0.1048×A+115.82 equation (1)

In one embodiment, although the saturated thickness is substantially linearly positively correlated with the substrate surface area, the saturated thickness is less dependent or substantially independent on the aspect ratio of the length to the width of the transparent substrate 101 under the same substrate surface area. Because the substrate thickness is equivalent to or larger than the saturated thickness for achieving better light-extraction efficiency, the substrate thickness (T_{sub}) preferably satisfies the following equation (2),

T_{sub}≧0.1048×A+115.82 equation (2)

Because the saturated thickness can be easily determined by the equation (1), thus the LED 100 is easily to achieve higher light-extraction efficiency by having the substrate thickness equal to or greater than the saturated thickness under specific substrate surface area. Take the LED 100 with the substrate surface area of 2025 mil² for example, the saturated thickness is 328.04 μm calculated from equation (1). Thus, when the substrate surface area is 2025 mil², the substrate thickness is determined to be higher than 328.04 μm for achieving better light-extraction efficiency. Besides, for the purpose of achieving higher lumens in single light-emitting device, the substrate surface area is preferred to be equal to or greater than 1 mm² or 2025 mil² for being used in a mobile device, lighting, display, or high power application. Base on the equation (2), when the substrate surface area is greater than 2025 mil², the substrate thickness is determined to be greater than 328.04 μm to achieve higher light-extraction efficiency.

There are various substrate sizes in practical applications of the LED 100. In order to produce the variety of the LEDs 100 with optimal light-extraction efficiency, it is preferable to predetermine the saturated thickness of the LED 100 with specific substrate surface area in advance of manufacturing the LED 100. The present disclosure further comprises a method of manufacturing the LED 100 mentioned above, which comprises steps of:
(i) determining a substrate surface area and a saturated thickness corresponding to the substrate surface area;
(ii) providing a transparent substrate 101 having a starting thickness greater than the saturated thickness;
(iii) growing an epitaxial stack on the transparent substrate 101 by sequentially growing a buffer layer 108, a first semiconductor layer 105, an active layer 107, and a second semiconductor layer 106;
(iv) removing a portion of the light-emitting stack 102 to form a low-lying region 111 and expose a part of the first semiconductor layer 105;
(v) depositing a transparent conductive oxide layer 109 on the surface of the second semiconductor layer 106 by sputtering method or e-beam evaporation method;
(vi) forming a first electrode 103 electrically connecting to the first semiconductor layer 105 on the exposed first semiconductor layer 105 and a second electrode 104 electrically connecting to the second semiconductor layer 106 on the transparent conductive oxide layer 109;
(vii) forming a passivation layer 110 on the transparent conductive oxide layer 109 and the light-emitting stack 102;
(viii) dividing the epitaxial stack into a plurality of light-emitting stacks 102 on the transparent substrate 101;
(ix) determining a substrate thickness T_{sub} not less than the saturated thickness;
(x) treating the transparent substrate 101 such that the transparent substrate 101 has the substrate thickness T_{sub}; and
(xi) dicing the transparent substrate 101 by a laser, such as pico-second laser to form a plurality of light-emitting dies, i.e. LEDs 100 each with a substrate surface area, wherein the substrate thickness T_{sub} satisfying a light-extraction efficiency of each of the light-emitting dies decreased no more than 0.1% if the substrate thickness T_{sub} is decreased by 30 μm, or preferably, the substrate thickness T_{sub} satisfies the following equation, which is:

T_{sub}≧0.1048A+115.82.

When dicing the transparent substrate 101 by the pico-second laser to form a plurality of the plurality of light-emitting dies, the pulse width of the pico-second laser is relative short for effectively reducing the thermal interaction between the transparent substrate 101 and the laser beam. In particularly, the pulse width of the pico-second laser is less than 15 pico-seconds to increase the efficiency for dicing the transparent substrate 101. The pico-second laser comprises a UV laser, a green light laser, a near-infrared laser, or a CO₂ laser. Moreover, the starting thickness of the transparent substrate 101 in step (ii) is selected from various commercialized thicknesses of various commercialized substrates from various substrate providers. For example, If the substrate surface area is determined as 2045 mil² in step (i), the transparent substrate 101 is provided to have a starting thickness selected from a commercial thickness closest to and greater than the saturated thickness calculated from equation (1), i.e. 328.04 μm to minimize the cost for treating the transparent substrate 101 in step (x). In another embodiment, the step (iii) is alternatively performed by bonding an epitaxial stack comprising the first semiconductor layer 105, the active layer 107, and the second semiconductor layer 106 to the transparent substrate 101 through the buffer layer 108, which acts as a bonding layer for bonding the epitaxial stack to the transparent substrate 101.

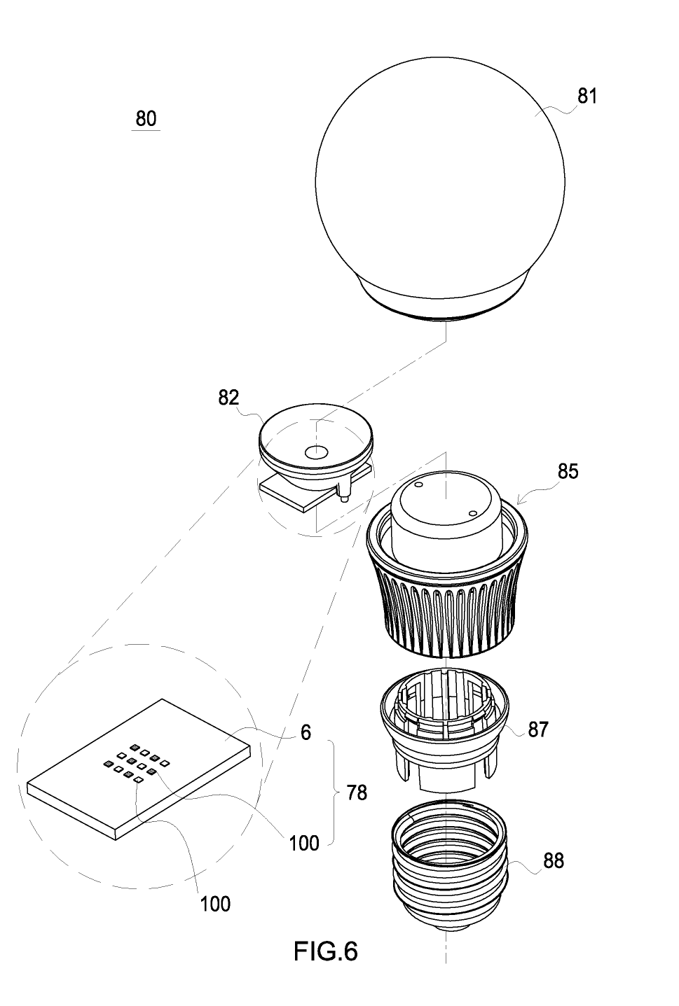

FIG. 6 shows a lighting apparatus comprising the LED 100 in accordance with one embodiment of the present disclosure. A lighting module 78, which comprising a plurality of the LEDs 100 on a second circuit board 6, is installed into a lighting bulb 80. The LEDs 100 can be connected in series or parallel by the circuit of the second circuit board 6 depending on the driving voltage to be applied. The lighting bulb 80 further comprises an optical lens 82 covering the lighting module 78, a heat sink 85 having a mounting surface where the lighting module 78 formed thereon, a protective shell 81 covering the lighting module 78 and connected to the heat sink 85, a frame 87 connected to the heat sink 85, and an electrical connector 88 connected to the frame 87 and electrically connected to the lighting module 78.

It is noted that the total thickness of layers above the transparent substrate 101 is much thinner than the transparent substrate 101 and the light-extraction effect thereof is much less than the transparent substrate 101 as well and don't make obvious difference of the light-extraction efficiency in comparison with that of the transparent substrate 101. As the result, any possible modifications of the thickness of the layers above the transparent substrate 101 should be covered by the disclosure. It should be noted that the proposed various embodiments are not for the purpose to limit the scope of the disclosure. Any possible modifications without departing from the spirit of the disclosure may be made and should be covered by the disclosure.

1-7. (canceled)

8. A light-emitting die, comprising:
a transparent substrate; and
a light-emitting stack formed on a surface of the transparent substrate, wherein the transparent substrate has a substrate surface area A (mil²) and a substrate thickness T_{sub} (μm) that satisfy the following relationship:
T_{sub}≧0.1048×A+115.82,
wherein T_{sub} represents a numerical part of the substrate thickness by taking “μm” as unit of substrate thickness, and A represents a numerical part of the substrate surface area by taking “mil²” as unit of substrate surface area.

9. The light-emitting die of claim 8, wherein the substrate surface area is greater than 2025 mil² and the substrate thickness is greater than 328.04 μm.

10. The light-emitting die of claim 8, wherein the transparent substrate has a rough surface where the light-emitting stack is formed.

11. The light-emitting die of claim 8, wherein the transparent substrate comprises single crystal sapphire.

12. The light-emitting die of claim 8, wherein the light-emitting stack comprises a buffer layer having single crystals or poly-crystals directly grown on the transparent substrate through epitaxial process.

13. The light-emitting die of claim 8, wherein the light-emitting stack is bonded to the transparent substrate through a bonding layer.

14-20. (canceled)
